(19) United States
(12) Patent Application Publication
(10) Pub. No.: US 2014/0090710 A1
(43) Pub. Date: Apr. 3, 2014

(54) INK DEPOSITION PROCESSES FOR THIN FILM CIGS ABSORBERS

(71) Applicant: PRECURSOR ENERGETICS, INC., Santa Clara, CA (US)

(72) Inventors: Kyle L. Fujdala, San Jose, CA (US); Zhongliang Zhu, San Jose, CA (US)

(73) Assignee: PRECURSOR ENERGETICS, INC., Santa Clara, CA (US)

(21) Appl. No.: 13/631,903

(22) Filed: Sep. 29, 2012

(51) Int. Cl. H01L 31/18; H01L 31/032

(52) U.S. Cl. CPC H01L 31/18; H01L 31/0322
USPC 136/262; 438/95

(57) ABSTRACT

Efficient processes for making thin film CIGS photovoltaic light absorber materials on a substrate. The processes involve depositing CIGS polymeric precursor inks in combination with depositing indium gallium selenide molecular precursor inks onto a substrate.

### BACKGROUND

A thin film solar cell can be made by depositing a thin, light-absorbing, solid film of the material copper indium gallium diselenide, known as “CIGS,” on a substrate.

One way to make a thin film of CIGS material is to deposit a CIGS polymeric precursor ink and an indium gallium selenide molecular precursor ink onto a substrate. The inks can be converted to thin films which ultimately can be transformed into a CIGS photovoltaic material.

Indium/gallium selenide molecular precursor inks and CIGS polymeric precursor inks have been disclosed and described in WO2011/017236 A2, WO2012/037382 A2, and PCT/US2012/028717.

In WO2011/017236 A2, WO2012/037382 A2, and PCT/US2012/028717, an indium/gallium selenide molecular precursor ink can be made containing a compound In(ER)₃ and/or a compound Ga(ER)₃, wherein E is S or Se, and R is independently selected, for each occurrence, from alkyl, aryl, heteroaryl, alkenyl, amido, and silyl. Inks, ink compositions, and processes for depositing indium/gallium selenide molecular precursor inks for making solar cells were also disclosed.

In WO2011/017236 A2, WO2012/037382 A2, and PCT/US2012/028717, a CIGS polymeric precursor ink contains a CIGS polymeric precursor compound that has the empirical formula Cuₓ(In_{1-y}Ga_{y})ᵥ((S_{1-z}Se_{z})R)_{w}, wherein x is from 0.5 to 1.5, y is from 0 to 1, z is from 0 to 1, v is from 0.5 to 1.5, w is from 2 to 6, and R represents R groups, of which there are w in number, which are independently selected from alkyl, aryl, heteroaryl, alkenyl, amido, and silyl. The ratio of Cu to (In+Ga) can be deficient, i.e. less than 1, or enriched, i.e. greater than 1. The ratio Cu:(In+Ga) can be from 1:3 up to 3:1, in other words from 0.33 up to 3.0. In general, a CIGS polymeric precursor compound may be deficient in Cu, when the ratio of Cu to (In+Ga) is less than one, or enriched in Cu, when the ratio of Cu to (In+Ga) is greater than one. Inks, ink compositions, and processes for depositing CIGS polymeric precursor inks for making solar cells were also disclosed.

In making CIGS thin film photovoltaic absorber layers, precursor inks can be deposited on a substrate and transformed into the ultimate photovoltaic absorber layer. A number of layers of ink can be required to achieve a desired thickness of the absorber layer. In other words, a number of passes of depositing an ink on a substrate can be required. The efficiency of a process for making a CIGS thin film absorber layer can be affected by the number of passes required.

There is a general need for processes to make thin film CIGS materials that require few passes to achieve a desired thickness.

What is needed are manufacturing processes to produce CIGS materials for photovoltaic absorber layers.

### BRIEF SUMMARY

In some aspects, this invention provides processes for making photovoltaic absorber layers by efficient deposition of precursor inks. Processes of this invention can achieve a desired thickness of the absorber layer by depositing few layers of precursor inks.

This invention relates to processes for making thin film CIGS photovoltaic absorber materials. In particular, this invention relates to processes for depositing CIGS polymeric precursor inks in combination with indium gallium selenide molecular precursor inks onto a substrate for making thin film CIGS absorber materials.

Embodiments of this disclosure include the following:

A process for making a thin film CIGS photovoltaic absorber material comprising:

(a) providing a substrate coated with an electrical contact layer;

(b) depositing one layer of a CIGS polymeric precursor ink onto the contact layer of the substrate, wherein the CIGS polymeric precursor ink contains a CIGS polymeric precursor compound enriched in copper so that the ratio of Cu to In plus Ga, Cu/(In+Ga), is from 1.3 to 3.0;

(c) heating the substrate at a temperature of from 100° C. to 450° C., thereby creating a thin film material on the substrate;

(d) repeating steps (b) and (c) from zero to two times, so that the total number of layers of CIGS polymeric precursor ink deposited is from one to three;

(e) depositing one layer of an indium gallium selenide molecular precursor ink onto the thin film material on the substrate, wherein the indium gallium selenide molecular precursor ink contains In(SeR)₃ and Ga(SeR)₃, wherein R is alkyl;

(f) heating the substrate at a temperature of from 100° C. to 450° C., thereby creating a thin film material on the substrate; and

(g) repeating steps (e) and (f) from zero to two times;

(h) annealing the thin film material on the substrate at a temperature of from 450° C. to 650° C., thereby providing a thin film CIGS photovoltaic absorber material; wherein the number of layers of CIGS polymeric precursor ink plus the number of layers of indium gallium selenide molecular precursor ink deposited is from two to four.

The process above, wherein the thickness of the layer made by one pass through steps (b) and (c), or made by one pass through steps (e) and (f) is from 100 to 750 nanometers.

The process above, wherein the thickness of the layer made by one pass through steps (b) and (c), or made by one pass through steps (e) and (f) is from 200 to 500 nanometers.

The process above, wherein the ratio of Cu to In plus Ga, Cu/(In+Ga) in the CIGS polymeric precursor compound is between 1.30 and 2.5.

The process above, wherein the ratio of Cu to In plus Ga, Cu/(In+Ga) in the CIGS polymeric precursor compound is between 1.70 and 2.1.

The process above, wherein the ratio of Ga to In plus Ga, Ga/(In+Ga), in the indium gallium selenide molecular precursor ink is from 0.01 to 0.99.

The process above, wherein the CIGS polymeric precursor compound has the empirical formula Cuₓ(In_{1-y}Ga_{y})(SeR)_{w}, wherein x is from 1.3 to 3.0, y is from 0.01 to 0.99, w is from 4.3 to 6, and the R groups are independently selected from alkyl groups.

The process above, wherein steps (e), (f) and (g) are performed before steps (b), (c) and (d), so that the indium gallium selenide molecular precursor ink is deposited on the substrate before the CIGS polymeric precursor ink.

The process above, wherein steps (b), (c) and (d) are performed again after steps (e), (f) and (g) so that layers of the indium gallium selenide molecular precursor ink and the CIGS polymeric precursor ink alternate.

The process above, further comprising applying heat, light, or radiation, or adding one or more chemical or crosslinking reagents to an ink before it is deposited.

The process above, further comprising optionally annealing the layers at a temperature of from 450° C. to 650° C. in the presence of Se vapor after any one of steps (c), (d), (f), or (g).

The process above, wherein the inks contain from 0.01 to 2.0 atom percent sodium ions.

The process above, further comprising exposing the substrate to chalcogen vapor.

The process above, wherein the depositing is done by spraying, spray coating, spray deposition, spray pyrolysis, printing, screen printing, inkjet printing, aerosol jet printing, ink printing, jet printing, stamp printing, transfer printing, pad printing, flexographic printing, gravure printing, contact printing, reverse printing, thermal printing, lithography, electrophotographic printing, electrodepositing, electroplating, electroless plating, bath deposition, coating, wet coating, dip coating spin coating, knife coating, roller coating, rod coating, slot die coating, meyerbar coating, lip direct coating, capillary coating, liquid deposition, solution deposition, layer-by-layer deposition, spin casting, solution casting, or any combination of the foregoing.

The process above, wherein the substrate is a glass, a molybdenum-coated glass, a metal, a molybdenum-coated metal, a metal foil, a molybdenum-coated metal foil, molybdenum, aluminum, molybdenum-coated aluminum, steel, molybdenum-coated steel, stainless steel, molybdenum-coated stainless steel, iron, molybdenum-coated iron, a metal alloy, a molybdenum-coated metal alloy, or a combination of any of the foregoing.

A thin film CIGS photovoltaic absorber material made by the process above. A photovoltaic device comprising the thin film CIGS photovoltaic absorber material above.

### BRIEF DESCRIPTION OF THE DRAWINGS

FIG. 1: FIG. 1 shows a schematic representation of embodiments of this invention in which layers of inks are deposited onto a substrate. The inks are indium gallium selenide molecular precursor inks or CIGS polymeric precursor inks. The combined layers are transformed to provide a CIGS photovoltaic material.

### DETAILED DESCRIPTION

This invention provides processes for making CIGS photovoltaic absorber layers using inks containing precursor compounds. The precursor inks contain indium gallium molecular precursor compounds which are CIGS polymeric precursor compounds that are enriched in Cu, so that the ratio of Cu:(In+Ga) is from 1.3:1 to 3.0:1.

In some aspects, a CIGS photovoltaic material is made using a layer of a CIGS polymeric precursor ink. The CIGS polymeric precursor ink contains a compound that is enriched in Cu and has the empirical formula Cuₓ(In_{1-y}Ga_{y})(SeR)_{w}, where x is from 1.3 to 3.0, y is from 0.01 to 0.99, and w is from 2 to 6. R represents R groups, of which there are w in number, which are independently selected from alkyl groups. The CIGS polymeric precursor ink contains a compound that is enriched in Cu, and the ratio of Cu to (In+Ga) is from 1.3 to 3.0. The value w=x+3, and therefore the range of w is from 4.3 to 6.

In some embodiments, the ratio of Cu to In plus Ga, Cu/(In+Ga), in each of the CIGS polymeric precursor compounds is between 1.30 and 2.5, preferably between 1.70 and 2.1.

The empirical formula for a CIGS polymeric precursor compound can be written different ways to reflect which atom is used to normalize the formula. For example, the CIGS polymeric precursor compound having the formula Cu_{1.5}In_{0.7}Ga_{0.3}(Se^{t}Bu)_{1.5}(SeⁿBu)_{3.0}, which is normalized for (In+Ga)=1, can also be written in an equivalent form as Cu_{1.0}In_{0.467}Ga_{0.2}(Se^{t}Bu)_{1.0}(SeⁿBu)_{2.0}, which is normalized for Cu=1. For any formula, the normalization of the formula is immediately apparent because the atom used to normalize the formula has a subscript of 1. If no atom in a formula has the subscript 1, then the formula can readily be normalized by dividing each subscript by the subscript of the atom that is desired to have the subscript of 1. Most formulas written herein are normalized for (In+Ga)=1.

In further aspects, a CIGS photovoltaic material is made using a layer of one or more indium gallium selenide molecular precursor inks. The indium gallium selenide molecular precursor inks contain a compound having the empirical formula In(ER)₃, and a compound having the empirical formula Ga(ER)₃, wherein each E is S or Se, and R is independently selected from alkyl groups.

It has been found that using a CIGS polymeric precursor ink that contains a compound enriched in Cu, so that the ratio of Cu to (In+Ga) is from 1.3 to 3.0, in combination with an indium gallium selenide molecular precursor ink containing In(ER)₃ and Ga(ER)₃, in a process of this disclosure can provide a thin film CIGS material in surprisingly few steps.

In a process of this disclosure, the thickness per pass is from 100 to 750 nanometers, preferably from 200 to 500 nanometers.

In certain aspects, a CIGS photovoltaic absorber material of from 1 to 2 micrometers in thickness, preferably from 1 to 1.5 micrometers in thickness, is made by depositing a total of from two to four layers of inks. The inks are selected from a CIGS polymeric precursor ink and an indium gallium selenide molecular precursor ink.

In some embodiments, a CIGS photovoltaic absorber material is made by depositing a total of from two to four layers of ink, wherein from one to three layers are a CIGS polymeric precursor ink, and the remaining layers, up to a total of four layers, are an indium gallium selenide molecular precursor ink.

In some embodiments, a CIGS photovoltaic absorber material is made by depositing one layer of a CIGS polymeric precursor ink, and three layers of an indium gallium selenide molecular precursor ink.

In some embodiments, a CIGS photovoltaic absorber material is made by depositing two layers of a CIGS polymeric precursor ink, and two layers of an indium gallium selenide molecular precursor ink.

In some embodiments, a CIGS photovoltaic absorber material is made by depositing three layers of a CIGS polymeric precursor ink, and one layer of an indium gallium selenide molecular precursor ink.

In some embodiments, a CIGS photovoltaic absorber material is made by depositing a total of two or three layers of ink, wherein from one to two layers are a CIGS polymeric precursor ink, and the remaining layer is an indium gallium selenide molecular precursor ink.

In some embodiments, a CIGS photovoltaic absorber material is made by depositing one layer of a CIGS polymeric precursor ink, and two layers of an indium gallium selenide molecular precursor ink.

In some embodiments, a CIGS photovoltaic absorber material is made by depositing two layers of a CIGS polymeric precursor ink, and one layer of an indium gallium selenide molecular precursor ink.

In some embodiments, a CIGS photovoltaic absorber material is made by depositing a single layer of a CIGS polymeric precursor ink, and a single layer of an indium gallium selenide molecular precursor ink.

In some embodiments, a CIGS photovoltaic absorber material is made by depositing a single layer of a CIGS polymeric precursor ink, and two layers of an indium gallium selenide molecular precursor ink, followed by a single layer of a CIGS polymeric precursor ink.

In some embodiments, a CIGS photovoltaic absorber material is made by depositing a single layer of a CIGS polymeric precursor ink, and a single layer of an indium gallium selenide molecular precursor ink, followed by a single layer of a CIGS polymeric precursor ink.

In some embodiments, a CIGS photovoltaic absorber material is made by depositing a single layer of a CIGS polymeric precursor ink, followed by a single layer of an indium gallium selenide molecular precursor ink, followed by a single layer of a CIGS polymeric precursor ink, followed by a single layer of an indium gallium selenide molecular precursor ink.

In some embodiments, a CIGS photovoltaic absorber material is made by depositing a total of from two to four layers of ink, wherein from one to three layers are an indium gallium selenide molecular precursor ink, and the remaining layers, up to a total of four layers, are a CIGS polymeric precursor ink.

In some embodiments, a CIGS photovoltaic absorber material is made by depositing one layer of an indium gallium selenide molecular precursor ink, and three layers of a CIGS polymeric precursor ink.

In some embodiments, a CIGS photovoltaic absorber material is made by depositing two layers of an indium gallium selenide molecular precursor ink, and two layers of a CIGS polymeric precursor ink.

In some embodiments, a CIGS photovoltaic absorber material is made by depositing three layers of an indium gallium selenide molecular precursor ink, and one layer of a CIGS polymeric precursor ink.

In some embodiments, a CIGS photovoltaic absorber material is made by depositing a total of two or three layers of ink, wherein from one to two layers are an indium gallium selenide molecular precursor ink, and the remaining layer is a CIGS polymeric precursor ink.

In some embodiments, a CIGS photovoltaic absorber material is made by depositing one layer of an indium gallium selenide molecular precursor ink, and two layers of a CIGS polymeric precursor ink.

In some embodiments, a CIGS photovoltaic absorber material is made by depositing two layers of an indium gallium selenide molecular precursor ink, and one layer of a CIGS polymeric precursor ink.

In some embodiments, a CIGS photovoltaic absorber material is made by depositing a single layer of an indium gallium selenide molecular precursor ink, and a single layer of a CIGS polymeric precursor ink.

In some embodiments, a CIGS photovoltaic absorber material is made by depositing a single layer of an indium gallium selenide molecular precursor ink, and two layers of a CIGS polymeric precursor ink, followed by a single layer of an indium gallium selenide molecular precursor ink.

In some embodiments, a CIGS photovoltaic absorber material is made by depositing a single layer of an indium gallium selenide molecular precursor ink, and a single layer of a CIGS polymeric precursor ink, followed by a single layer of an indium gallium selenide molecular precursor ink.

In some embodiments, a CIGS photovoltaic absorber material is made by depositing a single layer of an indium gallium selenide molecular precursor ink, followed by a single layer of a CIGS polymeric precursor ink, followed by a single layer of an indium gallium selenide molecular precursor ink, followed by a single layer of a CIGS polymeric precursor ink.

The above-mentioned examples are non-limiting, and additional ordering of the four layers is possible.

All of the CIGS polymeric precursor inks and compounds referred to herein are enriched in Cu so that the ratio of Cu to (In+Ga) is from 1.3 to 3.0.

The CIGS materials provided by a process of this invention are deficient in Cu so that the ratio of Cu to (In+Ga) is less than 1.

In some embodiments, the substrate was a Mo-coated sodalime glass substrate that was pre-treated with an adhesion promoting layer according to WO2012/037382 A2.

In each embodiment, each of the deposited layers is converted into a material film after being deposited. Subsequently, a combined material film is transformed to a CIGS photovoltaic material via an annealing process.

A layer of a precursor on a substrate can be converted to a material composition by applying energy using heat, light, or radiation, or by applying chemical energy.

The layers of CIGS polymeric precursor inks and indium gallium selenide molecular precursor inks can be deposited in any order, giving a total of from two to four layers of ink.

In making a CIGS photovoltaic absorber layer in a process of this disclosure the indium gallium selenide molecular precursor inks and the CIGS polymeric precursor inks can be deposited on a substrate in any order.

A layer of ink on a substrate can be converted to a material composition by applying energy to the layer or substrate. Energy can be applied using heat, light, or radiation, or by applying chemical energy.

The combined material film made by converting the deposited layers is transformed to the product CIGS photovoltaic material via an annealing process. The annealing process is optionally performed with selenium vapor present.

A CIGS thin film absorber of this disclosure can be manufactured reproducibly and in high yield.

### Methods and Compositions for Photovoltaic Absorber Layers

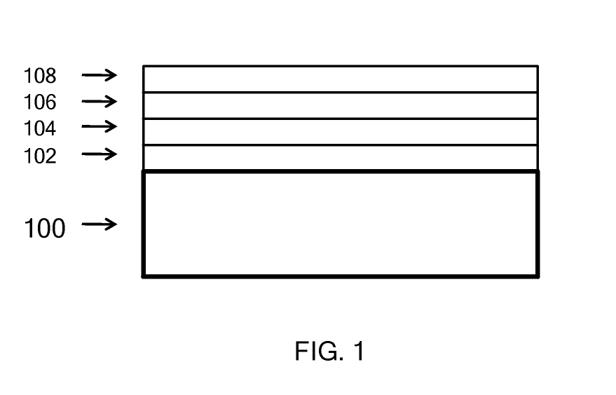

As shown in FIG. 1, a process to make a layered substrate can have steps for depositing up to four layers 102, 104, 106, and 108 on a substrate 100.

From one to three of the layers 102, 104, 106, and 108 can be a CIGS polymeric precursor ink layer. Any remaining layers that are not a CIGS polymeric precursor ink layer are indium gallium selenide molecular precursor ink layers.

In some embodiments, layer 102 is a CIGS polymeric precursor ink layer that is heated to form a thin film material layer (not shown). In some embodiments, layers 102 and 104, or layers 102, 104 and 106 are CIGS polymeric precursor ink layers that are heated to form a thin film material layer (not shown). The layers that are not a CIGS polymeric precursor ink layer are indium gallium selenide molecular precursor ink layers.

Each step of heating can transform any and all layers present on the substrate into a material layer. Thus, the schematic diagram in FIG. 1 represents steps of a process to make a layered substrate which ultimately may be transformed into a single thin film material layer on the substrate. The schematic diagram in FIG. 1 does not necessarily directly represent the structure of a product material or a substrate article formed from the process.

In certain embodiments, sodium ions may be introduced into any of the layers.

In various processes of this disclosure, a composition or material may optionally be subjected to a step of sulfurization or selenization.

In further embodiments, the groups R may independently be (C1-22)alkyl groups, or (C1-12)alkyl groups, or (C1-6)alkyl groups. In certain embodiments, the alkyl group may be a (C1)alkyl (methyl), or a (C2)alkyl (ethyl), or a (C3)alkyl (propyl), or a (C4)alkyl (butyl), or a (C5)alkyl (pentyl), or a (C6)alkyl (hexyl).

In some embodiments, a process of this disclosure may be used to prepare a CIGS photovoltaic absorber material on a substrate, wherein the CIGS photovoltaic absorber material has the empirical formula Cuₓ(In_{1-y}Ga_{y})Se_{w}, where x is from 0.7 to 1, y is from 0.01 to 0.99, and w is from 1.5 to 2.5.

In some aspects, the thickness of a CIGS absorber material is from 1 to 2 micrometers, preferably from 1.0 to 1.5 micrometers.

A substrate may have an electrical contact layer. The electrical contact layer can be on the surface of the substrate. An electrical contact layer on a substrate can be the back contact for a solar cell or photovoltaic device.

Examples of substrates of this disclosure include glass, a molybdenum-coated glass, a metal, a molybdenum-coated metal, a metal foil, a molybdenum-coated metal foil, molybdenum, aluminum, molybdenum-coated aluminum, steel, molybdenum-coated steel, stainless steel, molybdenum-coated stainless steel, iron, molybdenum-coated iron, a metal alloy, a molybdenum-coated metal alloy, or a combination of any of the foregoing.

An example of a substrate of this disclosure includes an organic polymer coated with an electrical contact.

A substrate of this disclosure can be of any thickness and any shape. Examples of substrates on which an ink of this disclosure can be deposited include a shaped substrate including a tube, a cylinder, a roller, a rod, a pin, a shaft, a plane, a plate, a blade, a vane, a curved surface or a spheroid.

As used herein, the term transition metals refers to atoms of Groups 3 though 12 of the Periodic Table of the elements recommended by the Commission on the Nomenclature of Inorganic Chemistry and published in IUPAC Nomenclature of Inorganic Chemistry, Recommendations 2005.

As used herein, the term atom percent, atom %, or at % refers to the amount of an atom with respect to the final material in which the atoms are incorporated. For example, “0.5 at % Na in CIGS” refers to an amount of sodium atoms equivalent to 0.5 atom percent of the atoms in the CIGS material.

The term “alkyl” as used herein refers to a hydrocarbyl radical of a saturated aliphatic group, which can be a branched or unbranched, substituted or unsubstituted aliphatic group containing from 1 to 22 carbon atoms. As used herein, the term “C(1-5)alkyl” includes C(1)alkyl, C(2)alkyl, C(3)alkyl, C(4)alkyl, and C(5)alkyl.

As used herein, an alkyl group may be designated by a term such as Me (methyl), Et (ethyl), Pr (any propyl group), ⁿPr (n-Pr, n-propyl), ⁱPr (i-Pr, isopropyl), Bu (any butyl group), ⁿBu (n-Bu, n-butyl), ⁱBu (i-Bu, isobutyl), ^{s}Bu (s-Bu, sec-butyl), and ^{t}Bu (t-Bu, tert-butyl).

While this invention has been described in relation to certain embodiments, aspects, or variations, and many details have been set forth for purposes of illustration, it will be apparent to those skilled in the art that this invention includes additional embodiments, aspects, or variations, and that some of the details described herein may be varied considerably without departing from this invention. This invention includes such additional embodiments, aspects, and variations, and any modifications and equivalents thereof. In particular, this invention includes any combination of the features, terms, or elements of the various illustrative components and examples.

The use herein of the terms “a,” “an,” “the” and similar terms in describing the invention, and in the claims, are to be construed to include both the singular and the plural.

The terms “comprising,” “having,” “include,” “including” and “containing” are to be construed as open-ended terms which mean, for example, “including, but not limited to.” Thus, terms such as “comprising,” “having,” “include,” “including” and “containing” are to be construed as being inclusive, not exclusive.

The examples given herein, and the exemplary language used herein are solely for the purpose of illustration, and are not intended to limit the scope of the invention. All examples and lists of examples are understood to be non-limiting.

When a list of examples is given, such as a list of compounds, molecules or compositions suitable for this invention, it will be apparent to those skilled in the art that mixtures of the listed compounds, molecules or compositions may also be suitable.

All publications, references, patents, patent publications and patent applications cited herein are each hereby specifically incorporated by reference in their entirety for all purposes.

### EXAMPLES

### Example 1

A photovoltaic absorber material was made by the following process.

A first ink containing a Cu-enriched CIGS polymeric precursor compound having the empirical formula {Cu_{2.0}In_{0.5}Ga_{0.5}(Se^{t}Bu)_{2.0}(SeⁿBu)_{3.0}} and 0.5 at % Na from NaIn(SeⁿBu)₄ in octane, 50% polymeric precursor content, by weight, was prepared under inert atmosphere. The resulting ink was filtered through a 0.2 μm PTFE syringe filter prior to use.

A second ink was made in an inert atmosphere by dissolving in a solvent the indium gallium molecular precursor compounds In(Se^{s}Bu)₃, Ga(SeⁿBu)₃, and Ga(Se^{s}Bu)₃, along with the sodium ion source compound NaGa(Se^{s}Bu)₄, so that the ratio of In:Ga was 50:50, the ratio of ⁿBu:^{s}Bu content was 1:4, and the amount of Na was 1.5 at %. The solvent was 20% 2-methyltetrahydrofuran and 80% octane (by weight). The precursor content was 50% by weight. The resulting ink was filtered through a 0.2 μm PTFE syringe filter prior to use.

An 0.06 mL aliquot of the first ink was deposited in a single layer onto a Mo-coated sodalime glass substrate using a knife coater at 7.5 mm/sec in an inert atmosphere glove box. The wet substrate was heated on a pre-heated 150° C. hot plate for 1 minute, followed by heating at 350° C. on a pre-heated hot plate for 5 minutes. One additional layer of the first ink was deposited and heated in a like manner.

An 0.06 mL aliquot of the second ink was deposited onto the film on the substrate made from the first ink by knife coating at 11 mm/sec. The wet substrate was heated on a pre-heated 150° C. hot plate for 1 minute followed by heating at 350° C. on a pre-heated hot plate for 5 minutes. Following this, one additional layer of the second ink was deposited and heated in a like manner.

The substrate was then heated in a pre-heated furnace at 530° C. for 10 minutes followed by heating at 530° C. for an additional 8 minutes while being exposed to Se vapor. The resulting annealed photovoltaic absorber thin film material on the substrate had a thickness of 1.2 μm.

### Example 2

A photovoltaic absorber material was made by the following process.

A first ink was made in an inert atmosphere by dissolving in a solvent the indium gallium molecular precursor compounds In(Se^{s}Bu)₃, Ga(SeⁿBu)₃, and Ga(Se^{s}Bu)₃, along with the sodium ion source compound NaGa(Se^{s}Bu)₄, so that the ratio of In:Ga was 50:50, the ratio of ⁿBu:^{s}Bu content was 1:4, and the amount of Na was 1.5 at %. The solvent was 20% 2-methyltetrahydrofuran and 80% octane (by weight). The precursor content was 50% by weight. The resulting ink was filtered through a 0.2 μm PTFE syringe filter prior to use.

A second ink containing a Cu-enriched CIGS polymeric precursor compound having the empirical formula {Cu_{2.0}In_{0.5}Ga_{0.5}(Se^{t}Bu)_{2.0}(SeⁿBu)_{3.0}} and 0.5 at % Na from NaIn(SeⁿBu)₄ in octane, 50% polymeric precursor content, by weight, was prepared under inert atmosphere. The resulting ink was filtered through a 0.2 μm PTFE syringe filter prior to use.

An 0.06 mL aliquot of the first ink was deposited in a single layer onto a Mo-coated sodalime glass substrate using a knife coater at 7.5 mm/sec in an inert atmosphere glove box. The wet substrate was heated on a pre-heated 150° C. hot plate for 1 minute, followed by heating at 350° C. on a pre-heated hot plate for 5 minutes. One additional layer of the first ink was deposited and heated in a like manner.

An 0.06 mL aliquot of the second ink was deposited onto the film on the substrate made from the first ink by knife coating at 11 mm/sec. The wet substrate was heated on a pre-heated 150° C. hot plate for 1 minute followed by heating at 350° C. on a pre-heated hot plate for 5 minutes. Following this, one additional layer of the second ink was deposited and heated in a like manner.

The substrate was then heated in a pre-heated furnace at 530° C. for 10 minutes followed by heating at 530° C. for an additional 8 minutes while being exposed to Se vapor. The resulting annealed photovoltaic absorber thin film material on the substrate had a thickness of 1.2 μm.

### Example 3

A photovoltaic absorber material was made by the following process.

A first ink was made in an inert atmosphere by dissolving in a solvent the indium gallium molecular precursor compounds In(Se^{s}Bu)₃, Ga(SeⁿBu)₃, and Ga(Se^{s}Bu)₃, along with the sodium ion source compound NaGa(Se^{s}Bu)₄, so that the ratio of In:Ga was 50:50, the ratio of ⁿBu:^{s}Bu content was 1:4, and the amount of Na was 1.0 at %. The solvent was 20% 2-methyltetrahydrofuran and 80% octane (by weight). The precursor content was 50% by weight. The resulting ink was filtered through a 0.2 μm PTFE syringe filter prior to use.

A second ink containing a Cu-enriched CIGS polymeric precursor compound having the empirical formula {Cu_{2.0}In_{0.5}Ga_{0.5}(Se^{t}Bu)_{2.0}(SeⁿBu)_{3.0}} and 1.0 at % Na from NaIn(SeⁿBu)₄ in octane, 50% polymeric precursor content, by weight, was prepared under inert atmosphere. The resulting ink was filtered through a 0.2 μm PTFE syringe filter prior to use.

An 0.07 mL aliquot of the first ink was deposited in a single layer using a knife coater at 12 mm/sec in an inert atmosphere glove box onto a Mo-coated sodalime glass substrate that was pre-treated with an adhesion promoting layer. The wet substrate was heated on a pre-heated 150° C. hot plate for 1 minute, followed by heating at 350° C. on a pre-heated hot plate for 5 minutes. One additional layer of the first ink was deposited and heated in a like manner.

An 0.06 mL aliquot of the second ink was deposited onto the film on the substrate made from the first ink by knife coating at 8 mm/sec. The wet substrate was heated on a pre-heated 150° C. hot plate for 1 minute followed by heating at 350° C. on a pre-heated hot plate for 5 minutes. Following this, one additional layer of the second ink was deposited and heated in a like manner.

The substrate was then heated in a pre-heated furnace at 530° C. for 10 minutes followed by heating at 530° C. for an additional 8 minutes while being exposed to Se vapor. The resulting annealed photovoltaic absorber thin film material on the substrate had a thickness of 1.5 μm.

This photovoltaic absorber thin film material on the substrate, when finished into a solar cell, provided 14.9% efficiency of the conversion of light.

### Example 4

A photovoltaic absorber material was made by the following process.

A first ink containing a Cu-enriched CIGS polymeric precursor compound having the empirical formula {Cu_{2.0}In_{0.7}Ga_{0.3}(Se^{t}Bu)_{2.0}(SeⁿBu)_{3.0}} and 0.5 at % Na from NaIn(SeⁿBu)₄ in octane, 50% polymeric precursor content, by weight, was prepared under inert atmosphere. The resulting ink was filtered through a 0.2 μm PTFE syringe filter prior to use.

A second ink was made in an inert atmosphere by dissolving in a solvent the indium gallium molecular precursor compounds In(Se^{s}Bu)₃ and Ga(Se^{s}Bu)₃, along with the sodium ion source compound NaGa(Se^{s}Bu)₄, so that the ratio of In:Ga was 70:30, the ratio of ⁿBu:^{s}Bu content was 1:10, and the amount of Na was 1.0 at %. The solvent was 15% 2-methyltetrahydrofuran and 85% octane (by weight). The precursor content was 55% by weight. The resulting ink was filtered through a 0.2 μm PTFE syringe filter prior to use.

An 0.06 mL aliquot of the first ink was deposited in a single layer using a knife coater at 5 mm/sec in an inert atmosphere glove box onto a Mo-coated sodalime glass substrate that was pre-treated with an adhesion promoting layer. The wet substrate was heated on a pre-heated 150° C. hot plate for 1 minute, followed by heating at 320° C. on a pre-heated hot plate for 5 minutes. One additional layer of the first ink was deposited and heated in a like manner.

The substrate was then heated in a pre-heated furnace at 530° C. for 5 minutes while being exposed to Se vapor.

An 0.06 mL aliquot of the second ink was deposited onto the film on the substrate made from the first ink by knife coating at 9 mm/sec. The wet substrate was heated on a pre-heated 150° C. hot plate for 1 minute followed by heating at 350° C. on a pre-heated hot plate for 10 minutes. Following this, one additional layer of the second ink was deposited and heated in a like manner.

The substrate was then heated in a pre-heated furnace at 530° C. for 10 minutes followed by heating at 530° C. for an additional 8 minutes while being exposed to Se vapor. The resulting annealed photovoltaic absorber thin film material on the substrate had a thickness of 1.5 μm.

### Example 5

A photovoltaic absorber material was made by the following process.

A first ink was made in an inert atmosphere by dissolving in a solvent the indium gallium molecular precursor compounds In(Se^{s}Bu)₃, Ga(SeⁿBu)₃, and Ga(Se^{s}Bu)₃, along with the sodium ion source compound NaGa(SeⁿBu)₄, so that the ratio of In:Ga was 70:30, the ratio of ⁿBu:^{s}Bu content was 1:1.8, and the amount of Na was 1.0 at %. The solvent was 20% 2-methyltetrahydrofuran and 80% octane (by weight). The precursor content was 50% by weight. The resulting ink was filtered through a 0.2 μm PTFE syringe filter prior to use.

A second ink containing a Cu-enriched CIGS polymeric precursor compound having the empirical formula {Cu_{2.0}In_{0.7}Ga_{0.3}(Se^{t}Bu)_{2.0}(SeⁿBu)_{3.0}} and 0.5 at % Na from NaIn(SeⁿBu)₄ in octane, 50% polymeric precursor content, by weight, was prepared under inert atmosphere. The resulting ink was filtered through a 0.2 μm PTFE syringe filter prior to use.

An 0.06 mL aliquot of the first ink was deposited in a single layer using a knife coater at 13 mm/sec in an inert atmosphere glove box onto a Mo-coated sodalime glass substrate that was pre-treated with an adhesion promoting layer. The wet substrate was heated on a pre-heated 150° C. hot plate for 1 minute, followed by heating at 350° C. on a pre-heated hot plate for 5 minutes.

An 0.06 mL aliquot of the second ink was deposited onto the film on the substrate made from the first ink by knife coating at 5 mm/sec. The wet substrate was heated on a pre-heated 150° C. hot plate for 1 minute followed by heating at 350° C. on a pre-heated hot plate for 5 minutes.

An 0.06 mL aliquot of the first ink was deposited onto the film on the substrate using a knife coater at 13 mm/sec in an inert atmosphere glove box. The wet substrate was heated on a pre-heated 150° C. hot plate for 1 minute, followed by heating at 350° C. on a pre-heated hot plate for 5 minutes.

The substrate was then heated in a pre-heated furnace at 530° C. for 10 minutes followed by heating at 530° C. for an additional 8 minutes while being exposed to Se vapor. The resulting annealed photovoltaic absorber thin film material on the substrate had a thickness of 1.3 μm.

### Example 6

A photovoltaic absorber material was made by the following process.

A first ink containing a Cu-enriched CIGS polymeric precursor compound having the empirical formula {Cu_{2.0}In_{0.5}Ga_{0.5}(Se^{t}Bu)_{2.0}(SeⁿBu)_{3.0}} in octane, 50% polymeric precursor content, by weight, was prepared under inert atmosphere. The resulting ink was filtered through a 0.2 μm PTFE syringe filter prior to use.

A second ink was made in an inert atmosphere by dissolving in a solvent the indium gallium molecular precursor compounds In(Se^{s}Bu)₃, Ga(SeⁿBu)₃, and Ga(Se^{s}Bu)₃, along with the sodium ion source compound NaGa(Se^{s}Bu)₄, so that the ratio of In:Ga was 50:50, the ratio of ⁿBu:^{s}Bu content was 1:4, and the amount of Na was 1.5 at %. The solvent was 20% 2-methyltetrahydrofuran and 80% octane (by weight). The precursor content was 50% by weight. The resulting ink was filtered through a 0.2 μm PTFE syringe filter prior to use.

An 0.06 mL aliquot of the first ink was deposited in a single layer using a knife coater at 7.5 mm/sec in an inert atmosphere glove box onto a Mo-coated sodalime glass substrate that was pre-treated with an adhesion promoting layer. The wet substrate was heated on a pre-heated 150° C. hot plate for 1 minute, followed by heating at 350° C. on a pre-heated hot plate for 5 minutes.

An 0.07 mL aliquot of the second ink was deposited onto the film on the substrate made from the first ink by knife coating at 13 mm/sec. The wet substrate was heated on a pre-heated 150° C. hot plate for 1 minute followed by heating at 350° C. on a pre-heated hot plate for 5 minutes.

An additional 0.07 mL aliquot of the second ink was deposited onto the film on the substrate by knife coating at 13 mm/sec. The wet substrate was heated on a pre-heated 150° C. hot plate for 1 minute followed by heating at 350° C. on a pre-heated hot plate for 5 minutes.

An additional 0.06 mL aliquot of the first ink was deposited onto the film on the substrate by knife coating at 7.5 mm/sec. The wet substrate was heated on a pre-heated 150° C. hot plate for 1 minute followed by heating at 350° C. on a pre-heated hot plate for 5 minutes.

The substrate was then heated in a pre-heated furnace at 530° C. for 10 minutes followed by heating at 530° C. for an additional 8 minutes while being exposed to Se vapor. The resulting annealed photovoltaic absorber thin film material on the substrate had a thickness of 1.3 μm.

What is claimed is:

1. A process for making a thin film CIGS photovoltaic absorber material comprising:
(a) providing a substrate coated with an electrical contact layer;
(b) depositing one layer of a CIGS polymeric precursor ink onto the contact layer of the substrate, wherein the CIGS polymeric precursor ink contains a CIGS polymeric precursor compound enriched in copper so that the ratio of Cu to In plus Ga, Cu/(In+Ga), is from 1.3 to 3.0;
(c) heating the substrate at a temperature of from 100° C. to 450° C., thereby creating a thin film material on the substrate;
(d) repeating steps (b) and (c) from zero to two times, so that the total number of layers of CIGS polymeric precursor ink deposited is from one to three;
(e) depositing one layer of an indium gallium selenide molecular precursor ink onto the thin film material on the substrate, wherein the indium gallium selenide molecular precursor ink contains In(SeR)₃ and Ga(SeR)₃, wherein R is alkyl;
(f) heating the substrate at a temperature of from 100° C. to 450° C., thereby creating a thin film material on the substrate; and
(g) repeating steps (e) and (f) from zero to two times;
(h) annealing the thin film material on the substrate at a temperature of from 450° C. to 650° C., thereby providing a thin film CIGS photovoltaic absorber material;
wherein the number of layers of CIGS polymeric precursor ink plus the number of layers of indium gallium selenide molecular precursor ink deposited is from two to four.

2. The process of claim 1, wherein the thickness of the layer made by one pass through steps (b) and (c), or made by one pass through steps (e) and (f) is from 100 to 750 nanometers.

3. The process of claim 1, wherein the thickness of the layer made by one pass through steps (b) and (c), or made by one pass through steps (e) and (f) is from 200 to 500 nanometers.

4. The process of claim 1, wherein the ratio of Cu to In plus Ga, Cu/(In+Ga) in the CIGS polymeric precursor compound is between 1.30 and 2.5.

5. The process of claim 1, wherein the ratio of Cu to In plus Ga, Cu/(In+Ga) in the CIGS polymeric precursor compound is between 1.70 and 2.1.

6. The process of claim 1, wherein the ratio of Ga to In plus Ga, Ga/(In+Ga), in the indium gallium selenide molecular precursor ink is from 0.01 to 0.99.

7. The process of claim 1, wherein the CIGS polymeric precursor compound has the empirical formula Cuₓ(In_{1-y}Ga_{y})(SeR)_{w}, wherein x is from 1.3 to 3.0, y is from 0.01 to 0.99, w is from 4.3 to 6, and the R groups are independently selected from alkyl groups.

8. The process of claim 1, wherein steps (e), (f) and (g) are performed before steps (b), (c) and (d), so that the indium gallium selenide molecular precursor ink is deposited on the substrate before the CIGS polymeric precursor ink.

9. The process of claim 1, wherein steps (b), (c) and (d) are performed again after steps (e), (f) and (g) so that layers of the indium gallium selenide molecular precursor ink and the CIGS polymeric precursor ink alternate.

10. The process of claim 1, further comprising applying heat, light, or radiation, or adding one or more chemical or crosslinking reagents to an ink before it is deposited.

11. The process of claim 1, further comprising optionally annealing the layers at a temperature of from 450° C. to 650° C. in the presence of Se vapor after any one of steps (c), (d), (f), or (g).

12. The process of claim 1, wherein the inks contain from 0.01 to 2.0 atom percent sodium ions.

13. The process of claim 1, further comprising exposing the substrate to chalcogen vapor.

14. The process of claim 1, wherein the depositing is done by spraying, spray coating, spray deposition, spray pyrolysis, printing, screen printing, inkjet printing, aerosol jet printing, ink printing, jet printing, stamp printing, transfer printing, pad printing, flexographic printing, gravure printing, contact printing, reverse printing, thermal printing, lithography, electrophotographic printing, electrodepositing, electroplating, electroless plating, bath deposition, coating, wet coating, dip coating spin coating, knife coating, roller coating, rod coating, slot die coating, meyerbar coating, lip direct coating, capillary coating, liquid deposition, solution deposition, layer-by-layer deposition, spin casting, solution casting, or any combination of the foregoing.

15. The process of claim 1, wherein the substrate is a glass, a molybdenum-coated glass, a metal, a molybdenum-coated metal, a metal foil, a molybdenum-coated metal foil, molybdenum, aluminum, molybdenum-coated aluminum, steel, molybdenum-coated steel, stainless steel, molybdenum-coated stainless steel, iron, molybdenum-coated iron, a metal alloy, a molybdenum-coated metal alloy, or a combination of any of the foregoing.

16. A thin film CIGS photovoltaic absorber material made by the process of claim 1.

17. A photovoltaic device comprising the thin film CIGS photovoltaic absorber material of claim 16.
